(19) United States
(12) Patent Application Publication
(10) Pub. No.: US 2009/0321719 A1
(43) Pub. Date: Dec. 31, 2009

(54) NOVEL MATERIAL AND PROCESS FOR INTEGRATED ION CHIP

(75) Inventors: Ron FOLMAN, Rehovot (IL); Alexander Fayer, Herzelia (IL); Benny Hadad, Beer Sheva (IL); Amir Ben-Tal, Omer (IL); Amit Ben-Kish, Givat Ela (IL)

Correspondence Address: DR. MARK M. FRIEDMAN;C/O BILL POLKINGHORN - DISCOVERY DISPATCH, 9003 FLORIN WAY, UPPER MARLBORO, MD, 20772, US

(73) Assignee: Ben Gurion University of The Negev Research And Development Authority, Beer Sheva (IL)

(21) Appl. No.: 12/113,219

(22) Filed: May 1, 2008

(30) Foreign Application Priority Data
Nov. 2, 2005 (IL) 171738

(51) Int. Cl. H01L 29/06; H01L 23/48; H01L 21/28; H01L 21/20; H01L 29/12

(52) U.S. Cl. 257/25; 438/652; 438/478; 977/700; 257/E21.158; 257/E29.068; 257/E29.005; 257/E21.09

(57) ABSTRACT

An integrated ion chip for a large scale quantum device of interconnected ion (or other charged particles) traps each holding a small number of particles for a finite period of time, in a preferred embodiment using sapphire as the substrate, having an internal trapping, translation, and quantum manipulation zones and having a first set of electrodes and a second set of electrodes for trapping ions and for quantum manipulations, in a preferred embodiment using silicon carbide (and materials of similar characteristics) as a core structure material, and utilizing unique fabrication processes using micromachining and thin film techniques.

### FIELD AND BACKGROUND OF THE INVENTION

The present invention relates to storage and control of charged particles including “quantum objects” (sometimes referred to as ‘cold matter’ or ‘matter waves’), and in particular to the design and fabrication of a micro-scale integrated (i.e. monolithically fabricated) ion trap commonly named ‘ion cip’, using micromachining and thin film techniques.

A single ion chip can have one or more ion traps mounted on it. Ion traps have become an essential tool in several areas of physical science and technology, including mass spectroscopy, atomic frequency standards (i.e. clocks), sensors, precision atomic and molecular measurements, studies of fundamental quantum dynamics and quantum information science (such as quantum computing, quantum memory, and quantum communication and cryptography).

In general it is said that an ion trap is an essential device in quantum technology.

In contrast to conventional technology, in which quantum mechanics plays a supporting or sometime even a hindering role, some novel technology trends that emerged recently are mainly modeled according to the laws of quantum physics and use different quantum phenomena as their working mechanism.

A specific example of this is the contribution of the ion trap to quantum computing. In this application the single ion is used as a qubit. A qubit is a unit of quantum information (analogous to the classical ‘bit’). The information it holds is described by a state vector in a two-level quantum mechanical system which is formally equivalent to a two-dimensional vector space over the complex numbers.

A quantum computer is a device for computation that makes direct use of quantum mechanical phenomena, such as superposition and entanglement, to perform operations on data. The fundamental resources required for computing are means of storing and manipulating qubits.

A recent development of fault-tolerant quantum error correction codes facilitates the physical implementation of a reliable quantum computer from a host of relatively unreliable components, as long as each elementary component of the architecture has a probability of failure below an estimated threshold value of 10⁻⁴. Meeting this condition is still difficult, and is contingent on greatly increasing the number of extra qubits, (“ancilla” qubits) required. Fabrication of qubit sites for is large namber of qubits and their control is not easy, and depends on the physical layout, the applied technology and the design of the device components in the framework of the particular technology. A solid state integrated device (similar to classical computer chips) would enable such dense and robust packing of qubit sites and their control elements. However, such solid state qubits strongly interact

(are coupled) with their classical environment and hence their coherence time (the time in which they are able to maintain their quantum features) is small.

Another possibility is to utilize isolated ions as qubits. Here the qubits are much more isolated, and therefore the expected error rate due to coupling to the environment is smaller (i.e. long coherence time). This was proposed in 1995 by Cirac and Zoller who showed that a collection of trapped and cooled atomic ions in an ultra high vacuum system can satisfy these requirements, and can comprise promising quantum computer architecture.

In Cirac and Zoller's proposal, ions coned in a linear RF trap (a two dimensional Paul ion trap in which ions are confined in the axial dimension by means of an electric field at the ends of the trap, and in the radial dimensions by an RF field) are cooled, and form a stable spatial array whose motion is described by normal modes. Two internal levels in each ion form a qubit, referred to as a spin qubit. Typically, the spacing between ions (>1 μm) is large enough so that the direct coupling between the internal states of two adjacent ions is negligible. By using laser beams, the quantum bits are coupled to one another by virtue of the quantized collective motion of the ions in the trap, mediated by the Coulomb interaction.

The trapped ions approach is today a leading candidate for the realization of a quantum computer because the basic elements of quantum computation have already been experimentally demonstrated. In order not to lose the advantages of dense (scalable) and robust packing of solid state devices, the idea of the ‘ion cip’ has been brought forward, where traditionally cumbersome ion traps (i.e. the electrodes forming the sources of the trapping and manipulating fields) are manufactured with semiconductor type of techniques while the ions themselves are still in ultra high vacuum microns outside the chip, hence enjoying the best of both worlds: the isolation and long coherence times of the ions, as well as accuracy, scalability and robustness of a solid state device. This ion chip is the main focus of the present invention.

The present invention may be better understood with reference to the following scientific papers:
1. M. A. Nielsen and I. L. Chuang, Quantum Computation and Quantum Information, Cambridge Univ. Press, (2000).
2. D. Kielpinski. Entanglement and decoherence in a trapped-ion quantum register, Ph.D. Thesis, Univ. Colorado, 2001.
3. P. Shor, Fault-tolerant quantum computation, in 37th FOCS, (1994).
4. A. Steane, Error correction codes in quantum theory, Phys. Rev. Lett., 77, 793 (1996).
5. A. R. Calderbank and P. W. Shor, Good quantum error-correcting codes exist, Phys. Rev. A, 54, 1098, (1996).
6. B. Kane A silicon-based nuclear spin quantum computer, Nature, 393, 133, (1998).
7. T. Metodiev et al., A Brief Comparison: Ion-Trap and Silicon-Based Implementations of Quantum Computation, the 30^{th} Annual International Symposium on Computer Architecture San Diego, Calif., USA (9-11 Jun., 2003).
8. J. I. Cirac and P. Zoller, Quantum Computations with Cold Trapped Ions, Phys. Rev. Lett. 74, 4091 (1995).
9. D. Kieplinski and C. Monroe and D. Wineland Architecture for a large-scale ion-trap quantum computer, Nature, 417, 709, (2002).
10. D. Kielpinski, V. Meyer, M. Rowe, W. I. C. A. Sacket, C. Monroe, and D. Wineland A decoherence-free quantum memory using trapped ions, Science, 291, 1013, (1998).
11. M. A. Rowe, A. Ben-Kish, B. Demarco, D. Leibfried, V. Meyer, J. Beall, J. Britton, J. Hughes, W. M. Itano, B. Jelenkovic, C. Langer, T. Rosenband, and D. J. Winland, Transport of quantum states and separation of ions in a dual RF ion trap, Quantum Information and Computation, 1 Rinton Press, (2001).
12. B. DeMarco et. al., Experimental Demonstration of a Controlled-NOT Wave-Packet Gate, Phys. Rev. Lett., 89, 267901 (2002).
13. D. Leibfried et al., Experimental demonstration of a robust, high-fidelity geometric two ion-qubit phase gate, Nature, 422, 412 (2003).
14. J. I. Cirac and P. Zoller, A scalable quantum computer with ions in all array of microtraps, nature, 404, 579 (2000).
15. D. J. Wineland et al., Experimental Issues in Coherent Quantum-State Manipulation of Trapped Atomic Ions, J. Res. Natl. Inst. Stand. Technol. 103, 259 (1998).
16. Madsen, M. J., Hensinger, W. L., Stick, D., Rabehuk, J. A., Monroe, C., Planar ion trap geometry for microfabrication, Applied Physics B-Lasers and Optics, v 78, n, p 639-651, (5, March 2004),
17. M. A. van Eijkelenborg, M. E. M. Storkey, D. M. Segal, R. C. Thompson Ion dynamics in a novel linear combined trap International Journal of Mass Spectrometry v188 155 (1999).
18. J. Stolze and D. Suter, Quantum Computing: A Short Course from Theory to Experiment ISBN 3-527-404384-Wiley-VCH, Berlin (2004).
19. Leo Hollberg et al Quantum optics and quantum entanglement J. Opt B: Quantum Semiclass. Opt. 5, 457, (2003).
20. A. M. Steane, D. M. Lucas Quantum Computing with Trapped Ions, Atoms and Light Fortschritte der Physik, Volume 48′ Issue 9-11, Pages 839-858, (2000).
21. J. Chiaverini et al., Surface-Electrode Architecture for Ion-Trap quantum information processing, quant-ph/0501147, (2005).
22. P. W. Shor, Proc. 35^{th} Annu. Symp. Foundations of Computer Science (ed. S. Goldwasser) 124-134 IEEE Computer Society, Los Alamitos, (1994).
23. D. Stic, W. K. Hensiger, S. Olmschenk, M. J Madsen, K. Schwab, and C. Monroe, Ion Tap in a Semiconductor Chip, Nature Physics 2, 36-39 (Jan. 1, 2006). Published online (Dec. 11, 2005).
24. S. Stah et al., A Planar Penning trap, Bur. Phys. J. D32, 139 (2004)
25. G. Ciaramicoli, I. Marzoli and P. Tombesi, Scalable Quantum Processor with Trapped Electrons, Phys. Rev. Lett. 91, 017901 (2003).

Which are incorporated by reference for all purposes as if fully set forth herein.

The model device suggested in Ref [9] is realized using sequential laser micromachining techniques on alumina [11].

FIGS. 1a and 1b of the prior art illustrates a realization of a dual linear ion trap [11], FIG. 1a illustrates an idealized four-rod geometry ion trap 100, and FIG. 1b illustrates a wafer-stack implementation ion trap 200.

As shown in FIG. 1a, ion trap 100 includes a pair of rods serving as RF electrodes 101 and a pair of rods serving as control electrodes 102, with each rod of the RP ground and also control (DC) electrodes divided into fives electrodes 102a-102e. Between the four rods, there are ions, in ion trap 103a and in ion trap 103b.

As shown in FIG. 1b, ion trap 200 is constructed from a stack of metal-coated 200 μm—thick alumina wafers. Laser-machined slots in the alumina and plated gold traces create the desired electrode geometry. Gold traces of 0.5 μm thicknesses are made by evaporated gold deposited through a shadow mask onto the alumina. Subsequently, an additional 3 μm of gold is electroplated onto the electrodes, resulting in relatively smooth electrode surfaces at the 1 μm level. The widths of each two central slots 205 (400 μm) separate RF electrodes 201 from control electrodes 202a-202e.

The wafer spacing (360 μm) defines the resolution of the RF trap. In addition, between every two adjacent control electrodes, such as control electrode 202a and control electrode 202b, side slots 206 (10 μm wide) electrically isolate the different control electrodes. The control electrodes (held at RF ground) are arranged into five segments, namely into control electrodes 202a-202e for axial confinement. Uncoated areas 204 (on the sides of the central slot 205) are part of the holding substrate (wafer).

Radial confinement perpendicular to the axial direction) is provided by the ponder motive forces generated by the applied RF field [11,15]. By smoothly changing the electric potentials on the control-electrode segments, the trapping potential moves the ions between the two locations, ions traps 203a and ions traps 203b.

The method of laser micro-machining applied for the trap fabrication has typical restrictions concerning the sequential material processing. Furthermore, novel architectures which, for example, require 3D fabrication such as air bridges and high aspect ratio etching, are hard to implement. It also has a resolution limited to tens of microns and hence prohibits future miniaturization beyond this limit. The resolution limitation also creates surface roughness which is currently suspected of giving rise to unwanted ion-surface interaction due to possible consummations and patch potentials. Consequently, this will not enable dense packing of trap arrays or allow fabrication of complex architectures.

To conclude, the current state of the art can be summarized as follows:

1. The materials commonly used in the semiconductor industry such as silicon are incompatible with the needs of the ion chip. This is so mainly because of the high electric fields existing in these traps and the strong RF power (e.g. at 100 MHz) required for the operation of these traps. For example, standard silicon wafers (chips) strongly absorb RF radiation and thus hinder the trap operation. This is described in terms of a high loss tangent.

Loss tangent, a synonym for dissipation factor; is a quantification of loss in the capacitor. The loss tangent is the tangent of the phase angle relationship between capacitor voltage and capacitor current as the angle departs from the theoretical 90 degree value as a result of loss mechanisms within the capacitor.

2. The current designs of layers and stacks are not compatible with the requirements of monolithic fabrication which would enable accurate miniaturization and future integration with photonics and control/readout electronics.

3. Some of the commonly used fabrication tools such as laser micro-machining, are limited to simple geometries, produce coarse results, and have an adverse effect on the surface quality and resolution required for quantum technology.

4. In order to be able to run an algorithm, numerous qubits are required. The increase in the number of ions (qubits) in one trap gives rise to several problems, leading to the problem of the scalability and feasibility of such a computer (for example, see papers by D. Wineland). Hence, it would be instrumental to be able to move towards a segmented trap in which the chip has many different trapping sites, with different regions for different tasks, with a controlled path between them. Utilizing accurate and monolithic fabrication processes, which enable the realization of complex geometries and designs, is thus necessary.

5. Another problem with all ion traps is the anomalous heating originating in nearby surfaces. The ions are affected by close proximity environmental changes, causing them to heat, which reduces the coherence time, and trap lifetime of the ions. It is expected that higher-quality surfaces will significantly reduce the problem.

6. Additional attempts which were made included for example MBE (Molecular Beam Epitaxy) growth methods, but these enable only very limited types of materials, geometries, and thickness.

It would be highly advantageous to have a chip design for an ion trap (and any other charged particle) and fabrication process, which are versatile enough, so that they could facilitate the realization of a wide variety of trap geometries, and furthermore facilitate a whole host of matter wave quantum technology devices. As noted, it would open the way to combine the best of two worlds: on one hand, the isolated quantum system, the charged particle (e.g. ion) in a trap, with which a high degree of quantum control has been achieved, and on the other hand, the features of solid state devices, which enable a high level of scalability, parallel micro-machining, monolithic integration of very different micro-scale elements (e.g. electronics and photonics), dense packing, and complexity, while increasing accuracy and reducing price.

### SUMMARY OF THE INVENTION

The present invention relates to storage and control of charged particles including particles in quantum states, and in particular to the fabrication of a micro-scale ion trap on a chip, using micromachining and thin film techniques.

Integrated ion chip according to the present invention is a large scale quantum device of at least one ion (or charged particle) trap fabricated in a monolithic process, where a chip with numerous traps (as that required for a quantum computer) may also include interconnects between the traps.

The idea is based on a novel combination of materials and processes, based on sapphire as the substrate and SiC (and other similar materials) as a light and strong material for high aspect ratio geometries (the two being unique materials which have thus far not been used), which enables to address versatile requirements of geometry and other trap specifications. The two materials do not necessarily need to appear together in a certain device. They have to unique capabilities each in their own right.

According to the present invention an industrial fabrication process for implementing many ion (or other charged particle) traps on a single chip is presented.

Fabrication of an ion chip by means of micromachining and thin film technology posed a challenge to the inventors of the present invention.

For example, in the process flow we need to deposit a layer of Si in the sapphire (see FIGS. 17a and 17b) and then cool from 250 C. Different thermal expansion coefficients cause mechanical stress, and too much stress can lead to a breakdown of the fabrication process or to a deformation of the ion chip and thus in each fabrication step one has to optimize the specific materials and process. In this specific step several materials such as amorphous Si and poly crystalline Si were examined, and the deformation and stress between poly crystalline Si and amorphous Si to sapphire was analyzed (see FIGS. 41 and 42 respectively). In some cases, different materials are best suited for different end geometries of the device, so depending on the latter both the above materials may be considered. Finally, depending on the specific device design and the consequent process flow, there are also instabilities which need to be taken into account e.g. in certain conditions, amorphous silicon may have a negative expansion coefficient.

As used herein the specification and in the claims section that follows, the term “integrated ion chip” and the like substantially refer to a novel type of ion trap based device made by micro-machining and thin film technology, in a monolithic process.

As used herein the specification and in the claims section that follows, the term “ion trap” and the like substantially refer to a combination of electric or magnetic fields that captures ions (or other charged particles) in the region of a vacuum system or tube.

As examples, the two most common types of ion traps are the Penning trap and the Paul trap.

As used herein the specification and in the claims section that follows, the term “Penning trap” [24] and the like substantially refer to a device for the storage of charged particles using a constant magnetic field and a constant electric field.

This kind of trap is particularly well suited for precision measurements of properties of ions and stable subatomic particles (e.g. electrons) which have electric charge, but also for advanced quantum devices such as the quantum computer [25].

As used herein the specification and in the claims section that follows, the term “Paul trap” and the like substantially refer to an ion trap that uses static and radio frequency (RF) ˜1-300 MHz oscillating AC electric fields to trap ions like in a mass spectrometer that uses such a trap to analyze ions.

To further elucidate, contrary to a semi-conductor solid state device where the system of interest is within the chip (the electrons in the wafer in a classical computer chip), the system of interest in any ion chip, is external to the chip's solid materials. In this case the chip serves mainly as a kind of smart surface or smart interface for trapping the ions and manipulating and measuring their quantum states, using additional optics and electronics expected to be assembled on the same chip. The ion chip combines the best of two worlds: on the one hand the isolated quantum system (the ion), with which a high degree of quantum control has been achieved, and on the other hand, the features of solid state fabrication methods, which enables monolithic integration of very different elements (electronics and photonics), dense packing and complexity, while increasing accuracy and reducing price.

The compatibility of standard fabrication techniques with the requirements of the ion chip is not straightforward.

The electrodes of the microtrap present many challenging requirements. These include the mechanical, thermal, and electrical parameters such as toughness, layer adhesion, residual and thermal stresses, shape distortion, roughness, and the suppression of: mechanical vibrations; inhomogeneities; and “patch” potentials; electrical breakdowns, electrical and thermal noise, and residual electrical charge.

The fabrication is constrained by the current level of micromachining and lithographic techniques. Moreover, low tangent loss, low dielectric surface charging, and high resistance to electrical voltage breakdowns are essential requirements for the isolating materials.

According to the present invention the main fabrication consideration affecting the ion chip performance has been analyzed for a micro-trap model that can be fabricated using newly available micro-processing techniques. The device, according to the present invention, is comprised of two basic elements:
1. The holding structure (the wafer) which forms the mechanical backbone of the chip. Here we will make use—for the first time for the purpose of the ion chip—of sapphire which has several superior qualities (as explained. e.g. good ultra violet (UV) compatibility, low tangent loss, good heat conductivity, and high resistivity and field break point). To mold the sapphire as desired, recently established etching techniques are utilized.
2. The electrodes which produce the electric and magnetic fields (either AC or DC) and form the trap for the charged particle at a distance of a few micro-meters to a few hundred micrometers away from them. Here we will present an assortment of electrodes intended for a variety of purposes and applications, and show: a their compatibility in terms of monolithic fabrication with the sapphire substrate, and, b. their structural and material novelty in addressing the challenges facing ion traps. Specifically, a completely novel material in the context of ion chips, namely silicon carbide (SiC), is utilized.

The novelty of this invention is in the materials used, the fabrication processes used, and in the combinations of the materials and processes to optimally address the challenges as described previously, amd just as important to allow for a wide range of geometries such that future trap designs could also be realized with the proposed technique.

Following is a description of the different novel trap combinations, the realization of which this invention can support:

1. One-layer trap (sometimes referred to as a “planaar” trap). Here the ions are not between the electrodes as in FIG. 1, but above a layer or a closely spaced multi layer of electrodes, which occupy the surface of the chip. This configuration fits both the AC Paul trap (and sapphire is very adequate because of low absorption of RF fields) and the DC penning trap (and sapphire is very adequate because of high electric field break point which mean small electrode separation may be used opening the way to miniaturization). Here, several combinations are of interest and are made possible by the new sapphire etching techniques:
High aspect ratio sapphire etching capabilities allow for loading slots (see FIG. 38) which allow for the ion (or charged particle) source to be behind the trapping area, thus not contaminating the quantum operations area which must remain clean of contamination which causes unwanted particle-surface interaction.
High aspect ratio sapphire etching capabilities also allow for vertical cantilevers (see FIG. 39) which hold the electrodes close to the trapped particles (thus realizing a strong and high resolution trap), while the insulator (i.e. the sapphire) with its potentially hanmfili patch potentials “sees” the particle from a much larger distance. A similar effect can be achieved by horizontal SiC cantilevers above an etched area in the substrate.
The above vertical sapphire cantilevers also mean that very t layers of metal need to be used contrary to the present thick layers deposited in order to again increase the distance between the insulator and the charged particle. Thin layers are advantageous as they can be produced with much finer deposition methods thus enabling a much smaller surface roughness which in tam reduces harmful ion-surface effects.
   High aspect ratio sapphire etching capabilities also allow for vertical holes (“vias”) to be “drilled” through the wafer to enable electrical contacts (see FIG. 40) with central electrodes that may not have surface electrical contacts (usually referred to as “contact pads”) as other electrodes block any possible path between the central electrode and the external pads at the perimeter. The electrical contact is thus achieved from the back side of the chip.
The transparency of sapphire at the relevant wave lengths (from ultra violet to infra red) for ion spectroscopy, enables the construction of light wave guides for the integration of photonics.

2. Two-layer trap (sometimes referred to as a “3D” trap, which may accommodate two or more electrode layers). Here, contrary to the one-layer scenario, the ions are between the electrodes as in FIG. 1. Here, several combinations are of interest:
The sapphire is transparent and thus enables through “back alignment” to realize complex geometries requiring metal deposition on both sides of the wafer.
In combination with SiC horizontal cantilevers, complex electrode geometries can be realized. For example to realize an X Junction for ion transport between separated traps (so-called “segmented traps”), one would require high aspect ratio “air-bridge” electrodes. Any other required combination (e.g. for a linear trap) such as segmented electrodes (for DC axial trapping) and non-segmented electrodes (e.g. for radial RF trapping) are also made available by this technology.

In the following, we present in detail the latter, most complex, configuration; that of a two-layer trap, with SiC high aspect ratio, and electrically conductive micro-cantilever electrodes attached to an electrically isolated sapphire substrate.

A planar cantilever is a bridge built using cantilevers: structures that project horizontally into space, supported on only one end.

The planar cantilever's aspect ratio, which is the width of the planar cantilever divided by its height, is limited by allowable mechanical deflections in the cantilevers themselves, as well as by the mechanical stability of the cantilevers under electromechanical forces due to the applied RF and static voltages. Moreover, the deflection value can increase drastically as a result of stresses and stress gradient defects existing in real thin film structures, and especially in the multi-layer cantilevers. Additionally, both the finite conductivity of the thin planar electrodes, which have a resistance several orders of magnitude greater than the metal conductors typically used in ion macro-traps, and the RF power dissipation in the isolating structures, may induce heating of the quantized motion of the ions in the center of the trap.

Building ion chips using less common micromachining materials, according to the present invention, are more suitable, not only due to their extremely low loss tangent, but also due to their smoother surfaces and UV compatibility. UV light is the main laser light used to interact with some of the candidate ions for quantum computation, the materials must be chosen for their non-UV-absorption qualities.

A two-layers structure comprises a substrate having at least one stepped-through hole formed therein, where the trapped ions are located. The substrate material for the trap should have the attributes of transparency in the visual and UV range, resistance to heat, low loss tangent, high electrical resistance, high dielectric strength, low surface roughness, low secondary electron emission, and reasonable thermal conductivity. This material serves as an isolating layer for the conducting electrodes as well as a substrate able to withstand mechanical deformation.

These electrodes for a 2-layer trap are structured as three dimensional “box-like” beams, comprising a high-strength core, with one or more adhesion layers and one or more highly conducting electrical cover layers which are connected to electric contact pads situated on the substrate. The RF and DC fields used for trapping ions are applied through these pads to the conducting electrodes. The substrate can be fabricated from sapphire, alumina, or aluminum nitride, and the core layer of the electrode can be fabricated from silicon carbide, silicon nitride, or tungsten. The adhesion layers can be fabricated from titanium chromium, or tungsten and the conducting layers can be fabricated from gold, tungsten, or copper.

The two-layer ion trap has a three-dimensional structure. Two parallel planes create the structures for electric fields (up and down), while between these two planes, there is a space in which the ions are caught in the generated electric field.

According to the present invention there is provided an integrated ion chip including (a) a substrate having at least one trapping zone wherein the trapping zones are suitable for trapping and cooling ions and other charged particles, a quantum manipulation zone suitable for performing quantum manipulation and read-out, and a translation zone suitable for the translation of ions between the zones; (b) a first set of electrodes, having a beam air bridge formation, wherein each of said electrodes of first set of electrodes has two bases, one at each end of, wherein each one of said electrodes of first set of electrodes bases is disposed on said substrate upon one of said gradations in locations suitable for trapping ions or other charged particles; (c) a second set of electrodes, wherein each one of the electrodes of the second set of electrodes, has one base at one end of the electrode of second set of electrodes, wherein each one of the bases of second set of electrodes is disposed on the substrate upon one of the gradations in locations suitable for performing quantum manipulation on ions; and (d) electrical contacts disposed on the substrate of a quantity and in locations suitable for connecting to each of both the bases of first set of electrodes and to each of the bases of second set of electrodes.

According to further feature of the present invention each of the electrodes of the first set of electrodes and each of the electrodes of the second set of electrodes includes: (i) a core layer granting the electrode of the second set of electrodes mechanical structural integrity; (ii) a first adhesion layer coating on an external surface of the core layer, granting the electrode of the second set of electrodes an adhesive quality; (iii) a second adhesion layer coating an external surface of the core layer, granting the electrode of the second set of electrodes an adhesive quality; and (iv) a conductive layer coating on the first adhesion layer for granting the electrode of the second set of electrodes the required conductivity.

According to further feature of the present invention the substrate is made of sapphire.

According to further feature of the present invention the substrate is made of a material selected from a group consisting of sapphire, alumina, and aluminum nitride.

According to further feature of the present invention the core layer is made of silicon carbide, and the conductive layers are made of gold.

According to fiber feature of the present invention the core layer is made of silicon carbide, and the conductive layers are made of gold.

According to further feature of the present invention the core layer is made of a material selected from a group consisting of silicon carbide, silicon nitride, and tungsten.

According to further feature of the present invention the conductive layers are made of a material selected from a group consisting of gold, silver, tungsten and copper.

According to further feature of the present invention the adhesion layers are made of a material selected from a group consisting of titanium chromium and tungsten.

According to further feature of the present invention the substrate has a tangent loss, a breakdown field, and a Young modulus, at least as good as those of sapphire.

According to further feature of the present invention the core layer (of the cantilever electrodes) is made of material having a Young modulus, a density and a thermal conductivity at least as good as those of SiC, and low tangent loss as good as that of SiC.

According to the present invention there is provided a process for fabrication of an integrated ion chip, the process including the stages of: (a) a preliminary preparatory stage including the step of: (i) providing a substrate material having the external form of a three-dimensional cube, with dimensions and a first main side having a surface and a second main side having a surface; (b) a first etching stage in which internal zones in the substrate are designed on the first side, while at least part of the internal zones have gradated walls serving as gradations; (c) a first electrode construction stage in which electrodes are constructed to be connected to the substrate; and (d) a first removal stage in which excess materials left over from the process, which have no use as a component of the integrated ion chip, are removed from the substrate and from the electrodes.

According to the present invention the process for fabrication of an integrated ion chip further including the stages of: (e) a second etching stage in which internal zones in the substrate are designed in the second main side, while at least part of the internal zones have gradated walls serving as gradations; and (f) a second electrode construction step in which electrodes are constructed to be connected to the substrate.

According to the present invention the process for fabrication of an integrated ion chip flier including the stages of: (e) electroplating of an Au layer on the electrodes and on areas to serve as electrical contacts.

According to the present invention the process for fabrication of an integrated ion chip further including the preliminary preparatory stage Her includes the steps of: (ii)

polishing both of the main sides.

According to the present invention the process for fabrication of an integrated ion chip further including the preliminary preparatory stage further includes the steps of (iii) positions of seed layer on the entire surface of the first main side of the substrate; and (iv) spinning of photoresist on the entire surface of the first main side of the substrate.

According to the present invention the process for fabrication of an integrated ion chip further including the preliminary preparatory stage further includes the steps of: (v)
electroplating of a Ni mask through the photoresist; and (vi) stripping of the photoresist.

According to the present invention the process for fabrication of an integrated ion chip further including the preliminary preparatory stage further includes the steps of: (vii) removing the seed layer by means nickel etching.

According to the present invention the process for fabrication of an integrated ion chip the first etching stage includes the steps of: (i) deep reactive ion etching in chlorine-based plasma; and (ii) deposition of a seed layer on an entire surface of the first main side of the substrate.

According to the present invention the process for fabrication of an integrated ion chip the first etching stage further includes the steps of: (iii) spinning of photoresist; (iv) photoresist patterning; and (v) electroplating of Ni mask trough the photoresist.

According to the present invention the process for fabrication of an integrated ion chip the first etching stage Her includes the steps of: (vi) stripping the photoresist; (vii) removing the seed layer by nickel etching; and (viii) deep reactive ion etching in chlorine-based plasma.

According to the present invention the process for fabrication of an integrated ion chip the first electrode construction stage includes the steps of: (i) deposition of a Si layer and trench filling; and (ii) sprig of photoresist.

According to the present invention the process for fabrication of an integrated ion chip the first electrode construction stage Her includes the steps of: (iii) patterning of the photoresist; (iv) reactive ion etching of the Si in fluorine-based plasma; and (v) stripping of the photoresist.

According to the present invention the process for fabrication of an integrated ion chip the first electrode construction stage her includes the steps of: (vi) adhesion layer sputtering; SiC layer; and (viii) the SiC planarization.

According to the present invention the process for fabrication of an integrated ion chip the first electrode construction stage Her includes the steps of: (ix) adhesion layer sputtering; and (x) polymer spinning.

According to the present invention the process for fabrication of an integrated ion chip the first electrode construction stage further includes the steps of: (xi) polymer planarization; and then (xii) spinning of photoresist; and then (xiii) photoresist patterning; and (xiv) thermal evaporation of Au.

According to the present invention the process for fabrication of an integrated ion chip the first removal stage includes the steps of: (i) photoresist removal; (ii) wet etching; and (iii) polymer stripping.

According to the present invention the process for fabrication of an integrated ion chip the first removal stage further includes the steps of: (iv) selective isotropic etching of a silicon sacrificial layer.

According to the present invention the process for fabrication of an integrated ion chip the preliminary preparatory stage further includes the steps of: (i) positioning of seed layer on the entire surface of the first main side of the substrate; (ii) spring of fabrication on the entire surface of the first main side of the substrate; (v) electroplating of a Ni mask through the photoresist; and (vi) stripping of the photoresist; wherein the first etching stage includes the steps of: (i) deep reactive ion etching in chlorine-based plasma; and (ii) deposition of a seed layer on an entire surface of the of the first main side of the substrate; (iii) spinning of photoresist; (iv) the photoresist patterning; (v) electroplating of Ni mask through the photoresist; (vi) stripping of the photoresist; (vii) removing of the seed layer by nickel etching; and (viii) deep reactive ion etching in chlorine-based plasma; wherein the electrode construction stage includes the steps of: (i) deposition of a Si layer and trench filling; (ii) spinning of photoresist; (iii) the photoresist patterning; (iv) reactive ion etching of Si in fluorine-based plasma; (v) stripping of the photoresist; (vi) adhesion layer sputtering; (vii) SiC layer deposition; (viii) the SiC planarization; (ix) adhesion layer sputtering; (x) polymer spinning; (xi) the polymer planarization; (xii) spinning of photoresist; and then (xiii) photoresist patterning; and (xiv) thermal evaporation of Au; and wherein the removal stage includes the steps of: (i) photoresist removal; (ii) wet etching; (iii) polymer stripping; and (iv) selective isotropic etching of a silicon sacrificial layer.

According to further feature of the present invention integrated ion chip her including: (e) at least one cantilever made by high aspect ratio deep etching; (f) at least one hole in the substrate, for electrical contacts; and (g) at least one hole in the substrate, for charged particle loading.

According to further feature of the present invention each one of the electrodes of the second set of electrodes consisting of a simple flat structure of a flat like geometry.

According to further feature of the present invention each one of the electrodes of the second set of electrodes consisting of a simple plate structure of a box-like geometry for increased strength.

### BRIEF DESCRIPTION OF THE DRAWINGS

The invention is herein described, by way of example only, with reference to the accompanying drawings, wherein:

FIGS. 1a and 1b of the prior art are schematically illustrated realizations of dual linear ion traps.

FIGS. 2a-36b are schematic illustrations of a process of fabrication of a micro-scale two-layer (or more than two layers) integrated ion chip (egg. Paul trap as an example), using micromachining and thin film techniques.

FIG. 37a is a perspective view of a schematic illustration of an integrated ion chip of a preferred embodiment according to the present invention.

FIG. 37b is an enlarged perspective view of a schematic illustration of the area of connection of a crossed electrode to an electrical contact and to a gradation in the substrate of an integrated ion chip of a preferred embodiment according to the present invention.

FIG. 37c is an additional enlarged perspective view of a schematic illustration of the crossed electrode base, of an integrated ion chip of a preferred embodiment according to the present invention.

FIG. 38 is a perspective view of a schematic illustration of an integrated ion chip of a preferred embodiment according to the present invention, with high aspect ratio sapphire etching capabilities allowing for loading holes.

FIG. 39 is a perspective view of a schematic illustration of an integrated ion chip of a preferred embodiment according to the present invention, with high aspect ratio sapphire etching capabilities allowing for vertical cantilevers.

FIG. 40 is a perspective view of a schematic illustration of an integrated ion chip of a preferred embodiment according to the present invention, with high aspect ratio sapphire etching capabilities also allowing for vertical holes 303 (“vias”).

FIGS. 41 and 42 display simulation results of deformation and stress between amorphous Si and poly crystalline Si to sapphire.

FIG. 43 displays the simulation results of maximal displacement of a flat shape cantilever.

FIG. 44 displays the simulation results of maximal displacement of a box-shape cantilever.

FIGS. 45a-45c displays the simulations results of the mechanical oscillation frequencies for relevant sizes of box-shape structure cantilevers.

### DESCRIPTION OF THE PRFFERRFD EMBODIMENTS

The present invention is a micro-scale one-layer and two-layer (as well as multi-layer) integrated ion chip and a fabrication process of the integrated ion chip using micromachining and fin film techniques.

As an example, the principles and operation of a micro-scale two-layer integrated ion chip according to the present invention may be better understood with reference to the drawings and the accompanying description.

Before explaining at least one embodiment of the invention in detail, it is to be understood that the invention is not limited in its application to the details of construction and the arrangement of the components set forth in the following description or illustrated in the drawings.

Unless otherwise defined, all technical and scientific terms used herein have the same meaning as commonly understood by one of ordinary skill in the art to which is invention belongs. The materials, dimensions, methods, and examples provided herein are illustrative only and are not intended to be limiting.

The following list is a legend of the numbering of the application illustrations:
1 Sapphire substrate
2 Seed layer
3 Photoresist
4 Ni (nickel) electroplating layer
5 Si (silicon) layer
6 Adhesion layer
7 SiC (silicon carbide) layer
8 Polymer
9 Au (gold)
10 Internal space
100 Idealized four-rod geometry ion trap
101 Idealized four-rod geometry ion trap RF electrodes
103 a and 103b Ions in the four-rod geometry ion trap
200 Wafer-stack implementation ion trap
201 Wafer-stack implementation ion trap RF electrodes
202a-202e Wafer-stack implementation ion trap control electrodes
203a and 203b Tons in wafer-stack implementation ion trap
204 Uncoated areas
205 Central slots
206 Side slots
300 Integrated ion chip according to the present invention
301 Ion chip substrate
302a Quantum manipulation zone
302b Trapping zone
302c Translation zone
303 Ions in the integrated ion chip according to the present invention
304u and 304l First set of electrodes
304a and 304b Bases of first set of electrodes
304c Core layer
304d Adhesion layer
304e Conducting layer
305u and 305l Second set of electrodes
306a and 306b Electrical contacts
307 Electrical contact
308 Hole for loading particles, (etc.)
309 Holes for electrical contacts (vias)
310 Vertical cantilever
311 Pad
312 Electrode connected to pad
313 Electrode connected to via
314 Flat cantilever
315 Box shape cantilever

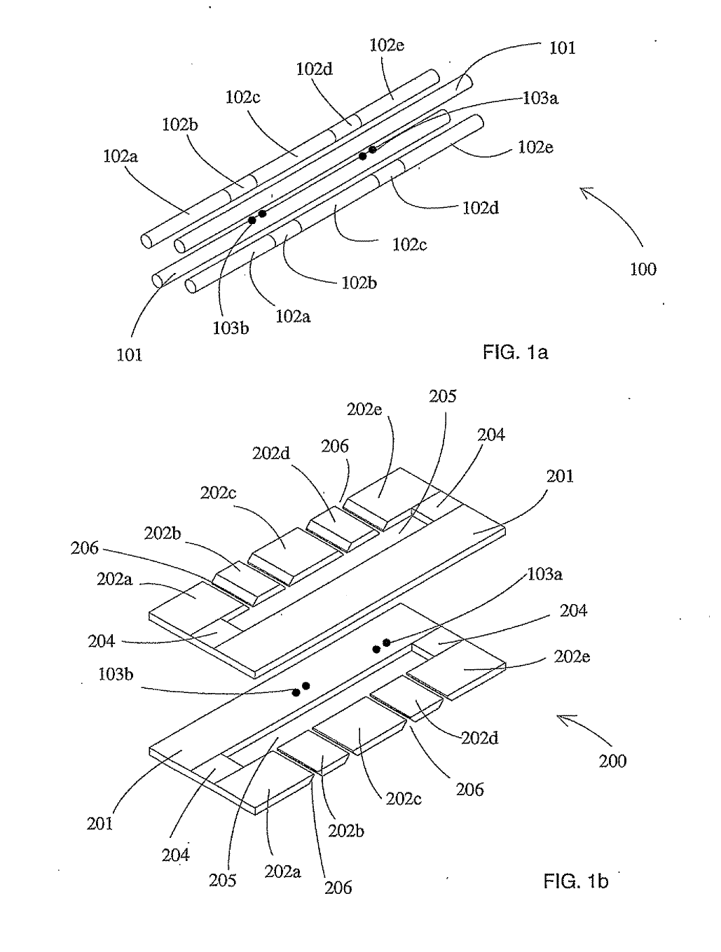

Referring now to the drawings, FIGS. 1a and 1b of the prior art schematically illustrate realizations of dual linear ion traps 100 and 200.

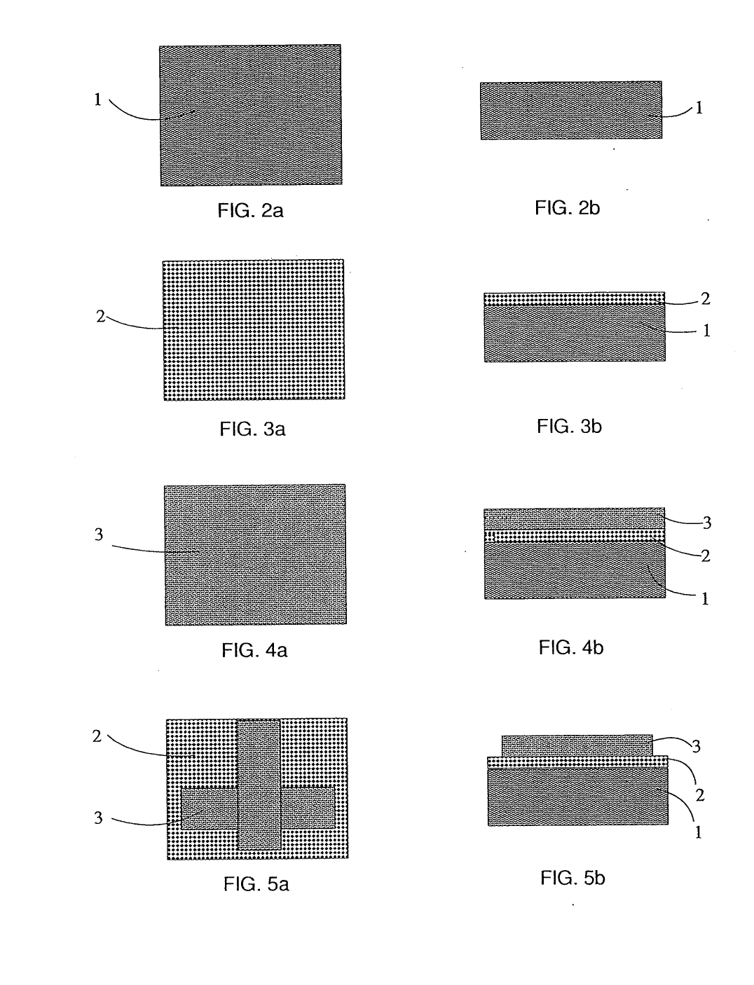

FIGS. 2a-36b are schematic illustrations of a process of fabrication of a micro-scale integrated ion chip (e.g. in this example a Paul trap), using micromachining techniques, according to the present invention.

The fabrication process includes four main stages, which are: a preliminary preparatory stage, in which a piece of the material composing the structure, which can, according to the present invention, also be sapphire, alumina, or aluminum nitride, is provided; the etching stages, in which the material composing the structure is designed to include the necessary spaces and gradations, for example starting with creation of a gradation at a limited depth and later creating an additional deeper gradation, in order to facilitate performance of this process; the electrode construction stage; and the stage of removal of all materials superfluous to the final structure.

The highest efficiency is achieved when the process is performed on one side of the material composing the structure, repeating the same steps on the other side, and putting finishing touches on the whole.

Each stage of the process can include its own steps. The steps shown in the illustration can be performed with partial overlapping, namely some of the steps of one step can be performed prior to the completion of other steps of a previous stage.

FIGS. 2a and 2b are schematic illustrations of a top view and a side view, respectively, of a fabrication step of a preferred embodiment according to the present invention which includes a double-side polished sapphire substrate 1, such as 300 μm (micrometer) thick.

FIGS. 3a and 3b are schematic illustrations of a top view and a side view, respectively, of a fabrication step of a preferred embodiment according to the present invention which includes deposition of a seed layer 2 on the entire surface of the substrate 1.

FIGS. 4a and 4b are schematic illustrations of a top view and a side view, respectively, of a fabrication step of a preferred embodiment according to the present invention which includes spinning of thick photoresist 3.

FIGS. 5a and 5b are schematic illustrations of a top view and a side view, respectively, of a fabrication step of a preferred embodiment according to the present invention which includes photoresist 3 patterning.

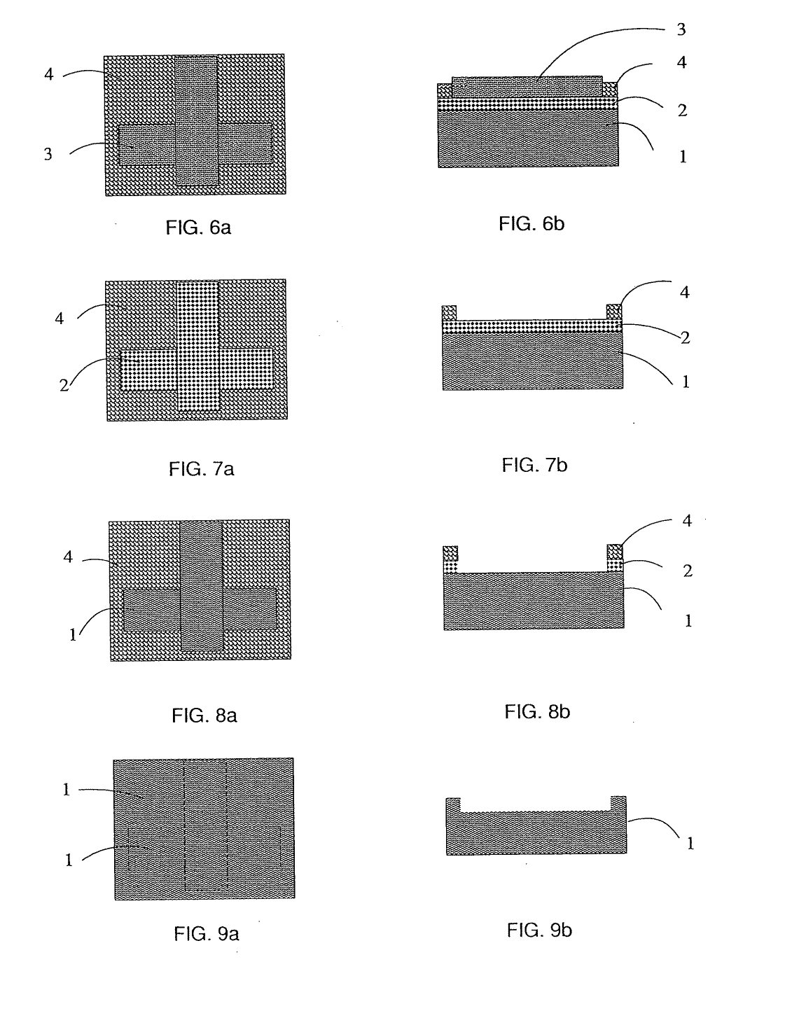

FIGS. 6a and 6b are schematic illustrations of a top view and a side view, respectively, of a fabrication step of a preferred embodiment according to the present invention which includes electroplating of a thick Ni 4 mask through photoresist 3.

FIGS. 7a and 7b are schematic illustrations of a top view and a side view, respectively, of a fabrication step of a preferred embodiment according to the present invention which includes photoresist stripping.

FIGS. 5a and 8b are schematic illustrations of a top view and a side view, respectively, of a fabrication step of a preferred embodiment according to the present invention which includes seed layer 2 removal by means of nickel 4 etching.

FIGS. 9a and 9b are schematic illustrations of a top view and a side view, respectively, of a fabrication step of a preferred embodiment according to the present invention which includes deep reactive ion etching (RIE) in chorine-based plasma.

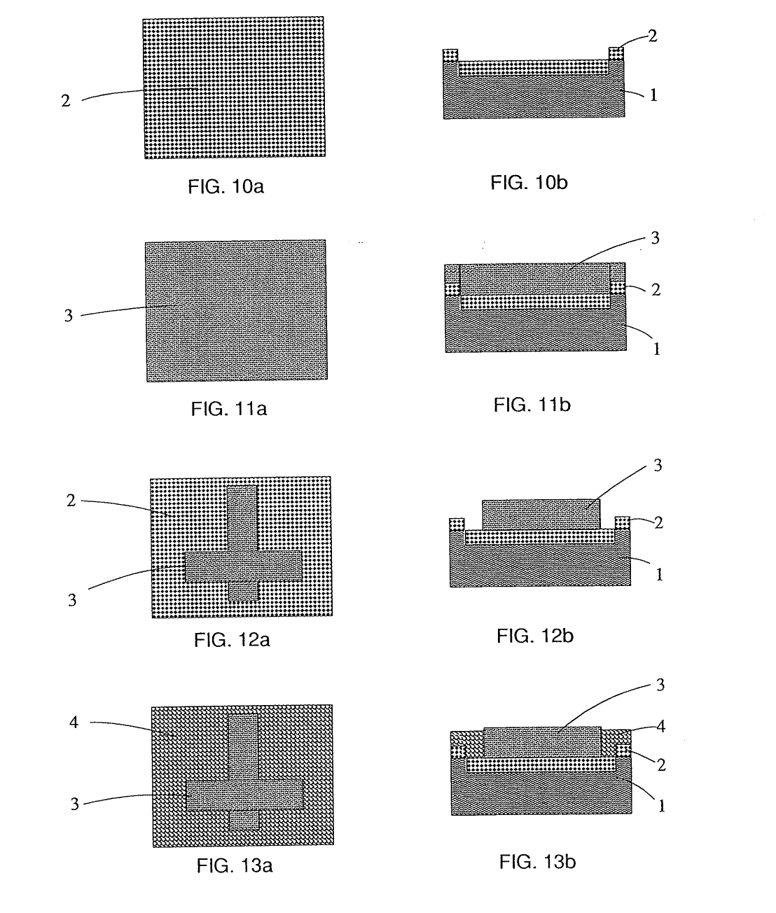

FIGS. 10a and 10b are schematic illustrations of a top view and a side view, respectively, of a fabrication step of a preferred embodiment according to the present invention which includes deposition of a seed layer 2 on the entire surface of the substrate 1.

FIGS. 11a and 11b are schematic illustrations of a top view and a side view, respectively, of a fabrication step of a preferred embodiment according to the present invention which includes spinning of thick photoresist 3.

FIGS. 12a and 12b are schematic illustrations of a top view and a side view, respectively, of a fabrication step of a preferred embodiment according to the present invention which includes photoresist 3 patterning.

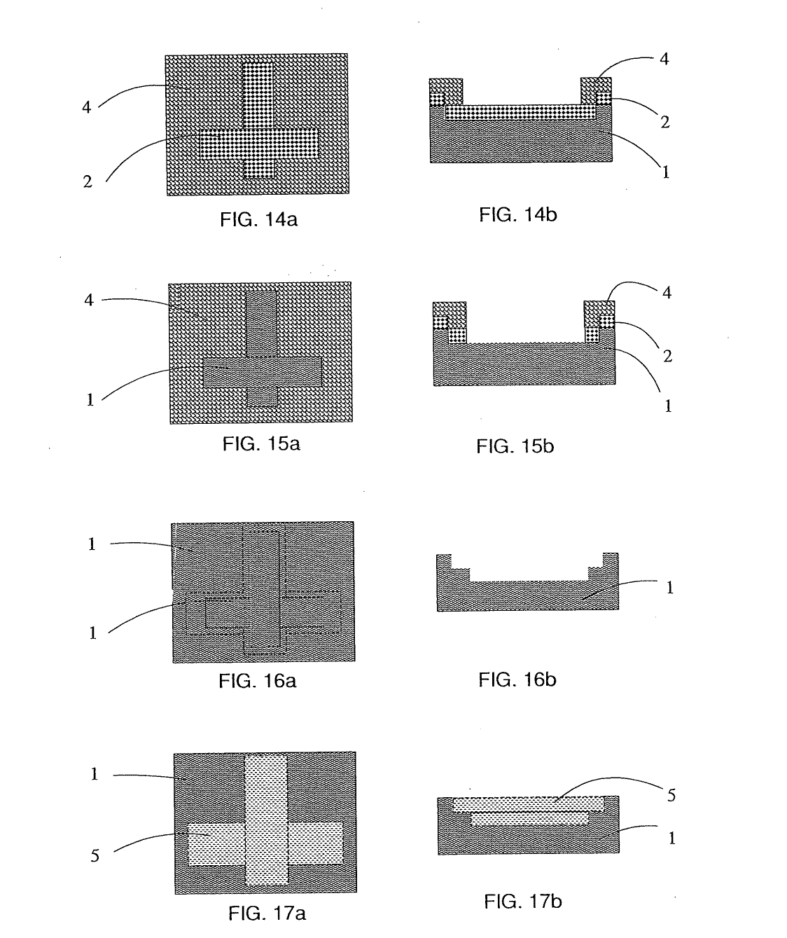

FIGS. 13a and 13b are schematic illustrations of a top view and a side view, respectively, of a fabrication step of a preferred embodiment according to the present invention which includes electroplating of thick Ni 4 mask through photoresist 3.

FIGS. 14a and 14b are schematic illustrations of a top view and a side view, respectively, of a fabrication step of a preferred embodiment according to the present invention which includes photoresist stripping.

FIGS. 15a and 15b are schematic illustrations of a top view and a side view, respectively, of a fabrication step of a preferred embodiment according to the present invention which includes seed layer 2 removal by means of nickel 4 etching.

FIGS. 16a and 16b are schematic illustrations of a top view and a side view, respectively, of a fabrication step of a preferred embodiment according to the present invention which includes deep reactive ion etching in chlorine-based plasma of approximately 100 μm.

FIGS. 17a and 17b are schematic illustrations of a top view and a side view, respectively, of a fabrication step of a preferred embodiment according to the present invention which includes deposition of a thick Si 5 layer and trench filling.

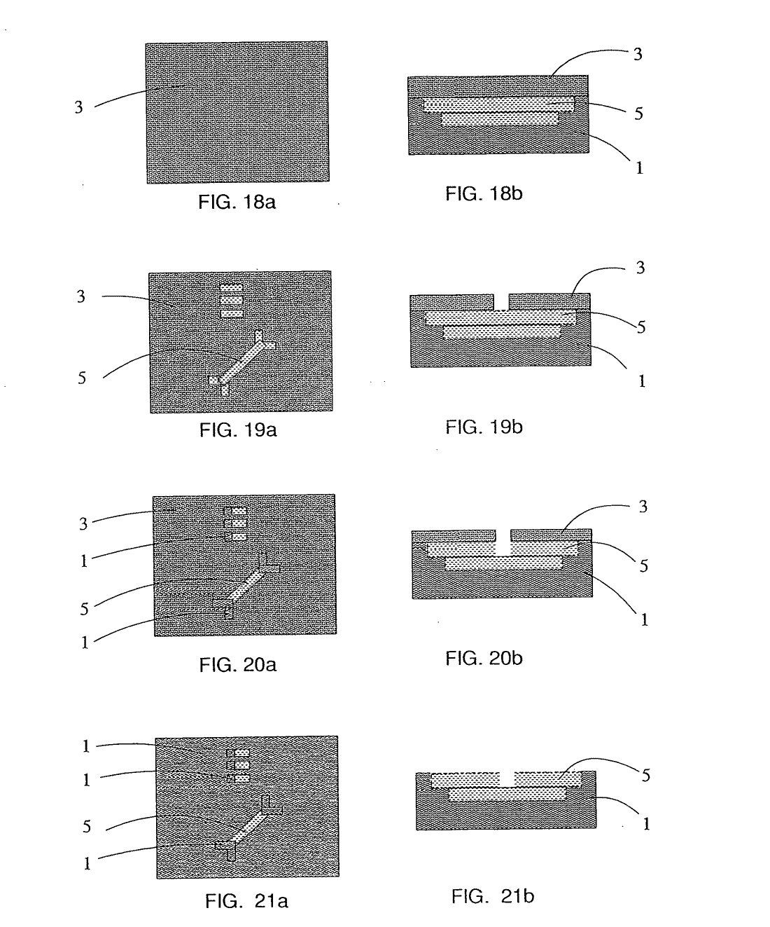

FIGS. 18a and 18b are schematic illustrations of a top view and a side view, respectively, of a fabrication step of a preferred embodiment according to the present invention which includes spinning of thick photoresist 3.

FIGS. 19a and 19b are schematic illustrations of a top view and a side view, respectively, of a fabrication step of a preferred embodiment according to the present invention which includes photoresist 3 patterning.

FIGS. 20a and 20b are schematic illustrations of a top view and a side view, respectively, of a fabrication step of a preferred embodiment according to the present invention which includes reactive ion etching of Si 5 in fluorine-based plasma.

FIGS. 21a and 21b are schematic illustrations of a top view and a side view, respectively, of a fabrication step of a preferred embodiment according to the present invention which includes photoresist stripping.

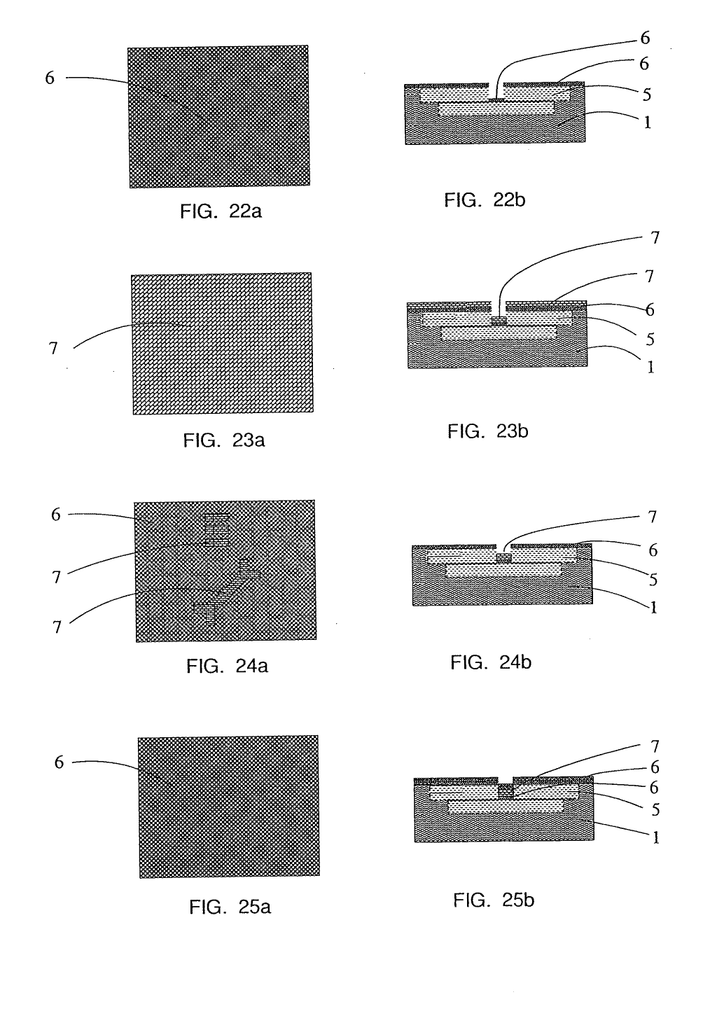

FIGS. 22a and 22b are schematic illustrations of a top view and a side view, respectively, of a fabrication step of a preferred embodiment according to the present invention which includes adhesion layer 6 sputtering.

FIGS. 23a and 23b are schematic illustrations of a top view and a side view, respectively, of a fabrication step of a preferred embodiment according to the present invention which includes a SiC 7 layer.

FIGS. 24a and 24b are schematic illustrations of a top view and a side view, respectively, of a fabrication step of a preferred embodiment according to the present invention which includes SiC 7 planarization.

FIGS. 25a and 25b are schematic illustrations of a top view and a side view, respectively, of a fabrication step of a preferred embodiment according to the present invention which includes adhesion layer 6 sputtering.

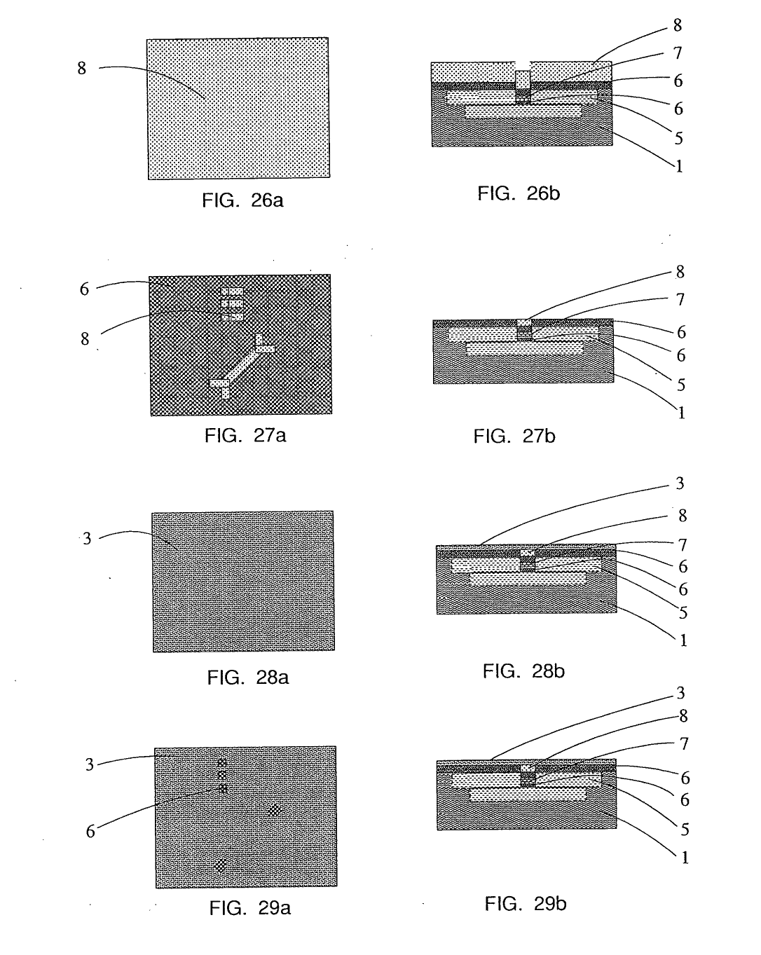

FIGS. 26a and 26b are schematic illustrations of a top view and a side view, respectively, of a fabrication step of a preferred embodiment according to the present invention which includes polymer 8 spinning.

FIGS. 27a and 27b are schematic illustrations of a top view and a side view, respectively, of a fabrication step of a preferred embodiment according to the present invention which includes polymer 8 planarization.

FIGS. 28a and 28b are schematic illustrations of a top view and a side view, respectively, of a fabrication step of a preferred embodiment according to the present invention which includes spinning of thick photoresist 3.

FIGS. 29a and 29b are schematic illustrations of a top view and a side view, respectively, of a fabrication step of a preferred embodiment according to the present invention which includes photoresist 3 patterning.

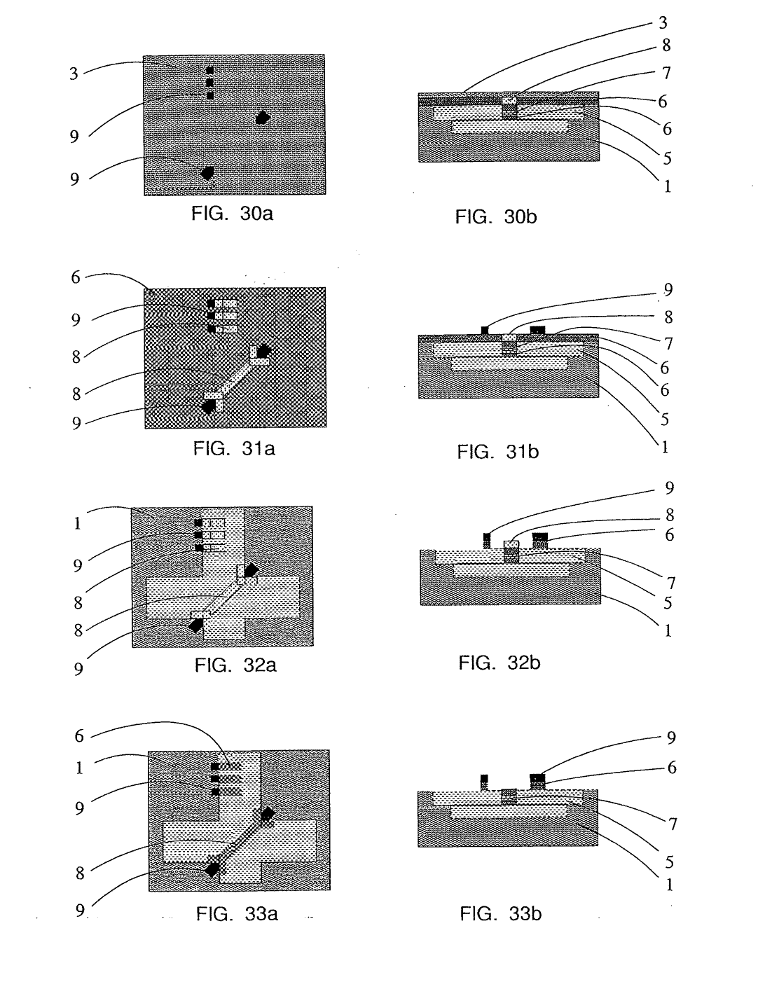

FIGS. 30a and 30b are schematic illustrations of a top view and a side view, respectively, of a fabrication step of a preferred embodiment according to the present invention which includes thermal evaporation of Au 9.

FIGS. 31a and 31b are schematic illustrations of a top view and a side view, respectively, of a fabrication step of a preferred embodiment according to the present invention which includes photoresist removal.

FIGS. 32a and 32b are schematic illustrations of a top view and a side view, respectively, of a fabrication step of a preferred embodiment according to the present invention which includes wet etching.

FIGS. 33a and 33b are schematic illustrations of a top view and a side view, respectively, of a fabrication step of a preferred embodiment according to the present invention which includes polymer stripping.

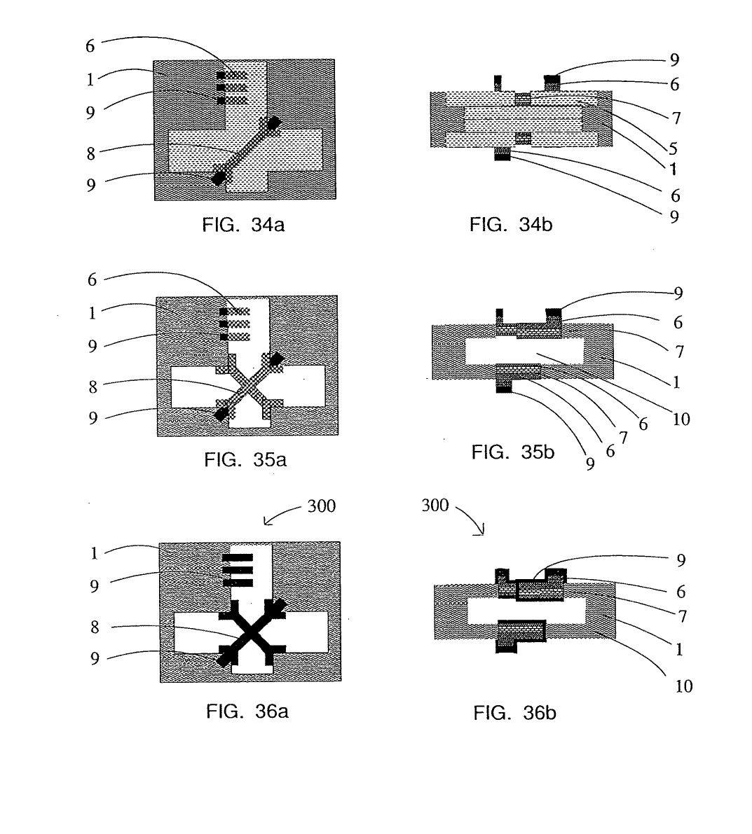

FIGS. 34a and 34b are schematic illustrations of a top view and a side view, respectively, of a fabrication step of a preferred embodiment according to the present invention which includes repetition of the previous steps on the other side of the material composing the structure.

FIGS. 35a and 35b are schematic illustrations of a top view and a side view, respectively, of a fabrication step of a preferred embodiment according to the present invention which includes selective isotropic etching of the silicon sacrificial layer.

FIGS. 36a and 36b are schematic illustrations of a top view and a side view, respectively, of a fabrication step of a preferred embodiment according to the present invention which includes electroplating of an Au 9 layer, achieving a complete structure of an ion chip according to a preferred embodiment of the present invention.

It is important to note that all of the dimensions specified in the description of the fabrication process and the description of the structure of the integrated ion chip are solely for the purpose of demonstration and are not in any way the only possible measurements nor are meant to serve as any form of limitation.

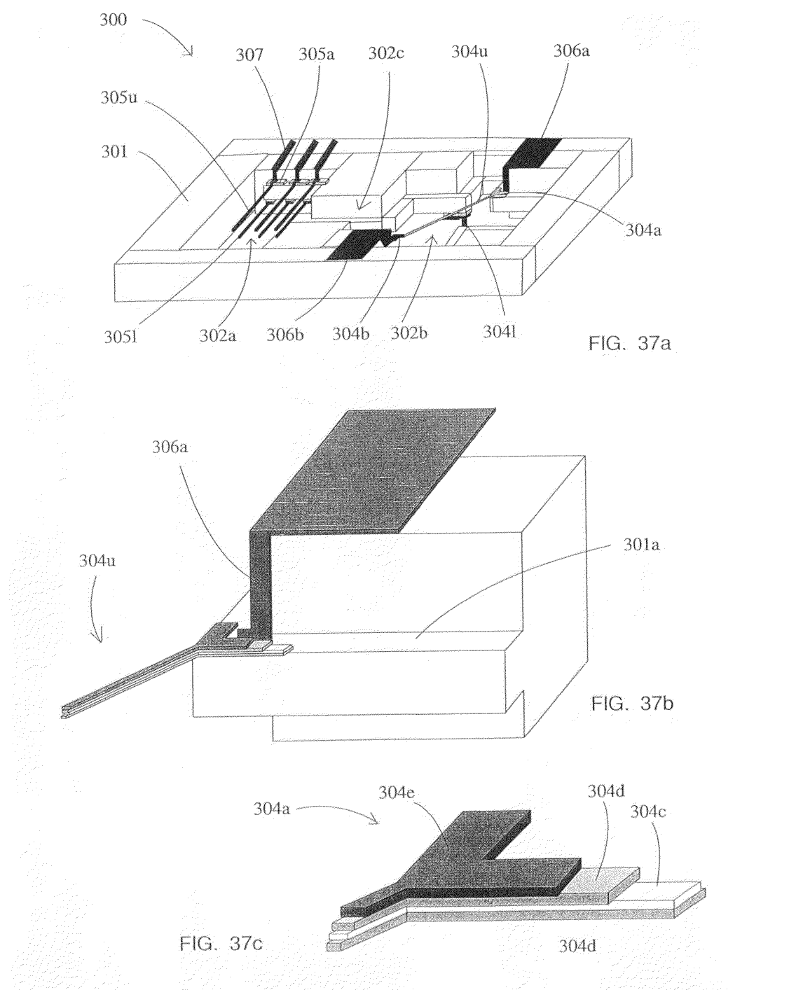

FIG. 37a is a perspective view of a schematic illustration of an integrated ion chip 300 of a preferred embodiment according to the present invention.

Integrated ion chip 300 that is built of a substrate 301, which is composed of a single piece, can be a cube composed of sapphire, and contain an internal space including gradations, as shown in the illustration, and which can serve as a mechanical structure for holding electrodes as well as electrical insulation. Other materials can be used for the same purpose, also including alumina or aluminum nitride.

Integrated ion chip 300 includes two groups of electrodes, in two separate zones. The first group includes a pair of electrodes which appear crossed from a top view, an upper crossed electrode 304u on an upper plane, and a lower crossed electrode 3041 on a lower plane parallel to the upper plane.

The upper crossed electrode 304u is structured as a beam (bridge) of a typical length of micro-meters to hundreds of micro-meters with a unique box-shaped cross section (see description of processes in the following) of typical dimensions of micro-meters, which has two bases 304a and 304b at its ends serving for physical connection both to the substrate 301 carrying it and to electrical contacts 306a and 306b.

Between both electrodes of the first set of electrodes 304u and 3041, a trapping zone 302b is formed, in which ions are trapped from a flowing supply of ions.

The second group of electrodes includes a second set of pairs of electrodes, three pairs in the case described in the illustration, each pair composed of an upper linear electrode 305u and a lower linear electrode 305l, which are parallel to each other and disposed on separate parallel planes. Each of the electrodes of the second set of electrodes 305u and 305l is structured as a beam (bridge) held at only one of its ends, of a typical length of micro-meters to hundreds of micro-meters with a unique box-shaped cross section (see description of processes in the following) of typical dimensions of micro-meters, which has a base 305a at one of its ends serving for physical connection both to substrate 301 carrying it and to an electrical contact 307.

The volume between the electrodes of the second set of electrodes serves as the quantum manipulation zone 302a, into which a single ion or several ions are moved from the trapping zone 302b. It is important to note again that the figure serves only as an example and not as the actual realization. For example, in linear quadrupole Paul traps (as shown in FIG. 1) one layer would be composed of segmented traps, while the one above or below would be composed of a long plate electrode.

The trapping is controlled by electrical fields, and moving of an ion or several ions from the trapping zone 302b to the quantum manipulation zone 302a through translation zone 302c by means of magnetic fields, laser radiation, or a combination of both.

The ability to realize an electrode structure such as the one described above, in which the electrodes are essentially hanging in the air, with each linear electrode held at only one end, is the result of use of the specially selected structure (box-like—see following) and strong material composing the core material of the electrode, while according to a preferred embodiment of the present invention, each electrode, in both zones, includes a core layer of silicon carbide (SiC), adhesion layers on either side, as well as a layer of gold (Au), achieving both the necessary strength and the necessary electrical qualities.

Even though the illustration shows integrated ion chip 300 including a certain number of electrodes of first set of electrodes and electrodes of second set of electrodes and of a specific three-dimensional spatial structure, according to the present invention, integrated ion chips may be structured of many various three-dimensional spatial geometries and having varying numbers of electrodes.

According to the present invention an industrial fabrication process for implementing many ion traps on a single integrated ion chip is presented.

FIG. 37b is a perspective enlarged view of a schematic illustration of the area of connection of the upper crossed electrode 304u to electrical contact 306a which can also be made of gold, tungsten, or copper, and to gradation 301a on the substrate of an integrated ion chip of a preferred embodiment according to the present invention. The illustration does not show upper crossed electrode 304u for its entire length, but shows the layers arbitrarily sectioned.

FIG. 37c is an additional enlarged perspective view of a schematic illustration of a crossed electrode base 304a, of an integrated ion chip of a preferred embodiment according to the present invention. The illustration does not show upper crossed electrode 304u for its entire length, but shows the layers arbitrarily sectioned. The illustration shows the layer structure of upper crossed electrode 304u which can be the layer structure of all of the integrated ion chip's electrodes.

The layer carrying the majority of the mechanical load and granting the electrode its mechanical strength is the core layer 304d which, according to a preferred embodiment of the present invention, is made of silicon carbide (SiC), however can also be made of silicon nitride or tungsten, and is coated on both sides with adhesion layers 304d, which can also be made of titanium, chromium, or tungsten, where the purpose of an adhesion layer is to firmly connect between two different materials on both sides of the adhesion layer.

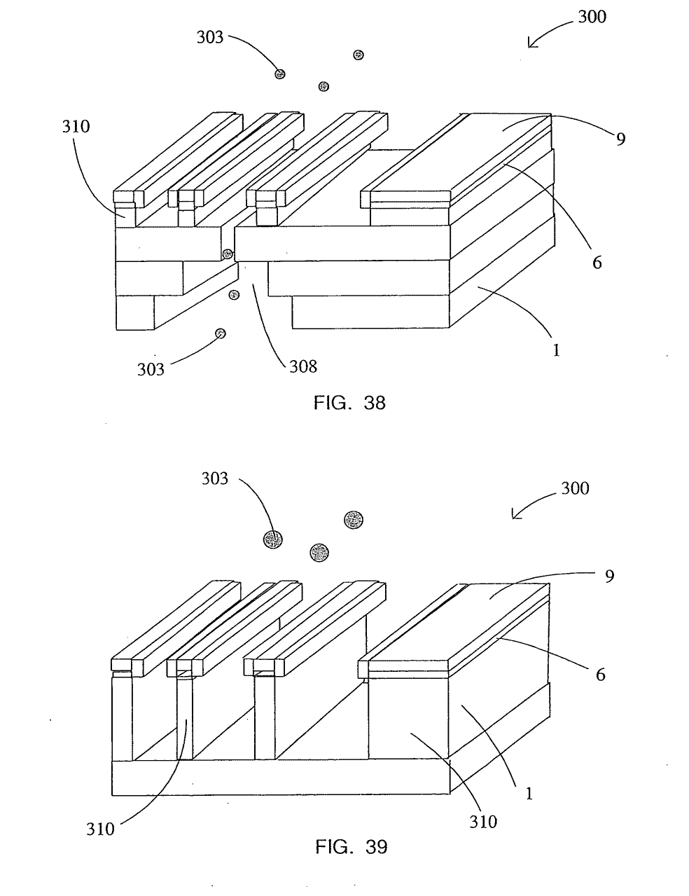

FIG. 38 is a perspective view of a schematic illustration of an integrated ion chip 300 of a preferred embodiment according to the present invention, with high aspect ratio sapphire 1 etching capabilities allow for loading holes 308, which can have slot geometry, which allows for the ion 303 (or charged particle) source to be behind the trapping area, thus not contaminating the quantum operations area which must remain clean of contamination which causes unwanted particle-surface interaction.

FIG. 39 is a perspective view of a schematic illustration of an integrated ion chip 300 of a preferred embodiment according to the present invention, with high aspect ratio sapphire 1 etching capabilities allow for vertical cantilevers which hold the electrodes whose surfaces can be a gold layer 9 deposited on an adhesion layer 6, close to the trapped particles (thus realizing a strong and high resolution trap), while the insulator (i.e. the sapphire) with its potentially harmful patch potentials “sees” the particle from a much larger distance. A similar effect can be achieved by horizontal SiC cantilevers above an etched area in the substrate.

The above vertical sapphire cantilevers 310 also mean that very thin layers of metal need to be used contrary to the present thick layers deposited in order to again increase the distance between the insulator and the charged particle. Thin layers are advantageous as they can be produced with much finer deposition methods thus enabling a much smaller surface roughness which in turn reduces harmful ion-surface effects.

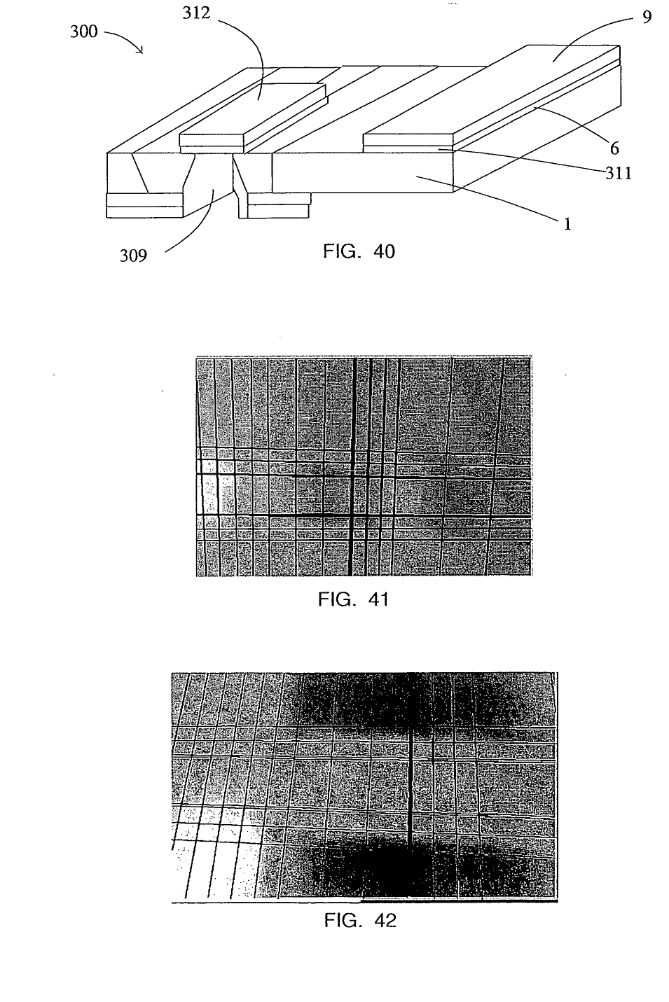

FIG. 40 is a perspective view of a schematic illustration of an integrated ion chip 300 of a preferred embodiment according to the present invention, with high aspect ratio sapphire 1 etching capabilities also allow for vertical holes 309 (“vias”) to be “drilled” through the wafer to enable electrical contacts with central electrodes 312 that may not have surface electrical contacts (usually referred to as “contact pads” 311) as other electrodes are blocking any possible path between the central electrode and the external pads at the perimeter. The electrical contact is thus being achieved from the back side of the chip.

FIG. 41 displays the simulation results of deformation and stress between amorphous Si and poly crystalline Si, and sapphire. The shades of gray in FIGS. 41 and 42 represent the values of the mechanical stress at each point of the material, according to a legend not shown in the illustration.

According to the simulation, poly crystalline Si experiences a maximal stress of 185 MPa for the thermal expansion coefficient of 29*10(−7)1/K.

FIG. 42 displays the simulation results of deformation and stress between amorphous Si and poly crystalline Si and sapphire. According to the simulation. amorphous Si experiences a maximal stress of 887 MPa, for a thermal expansion coefficient (worst case) of 70*10(−7) 1/K. Amorphous silicon has another thermal behavior. Its thermal expansion may be negative up to −70*10(−7) 1/K. In this worst case the maximal thermal stress reaches 650 MPa.

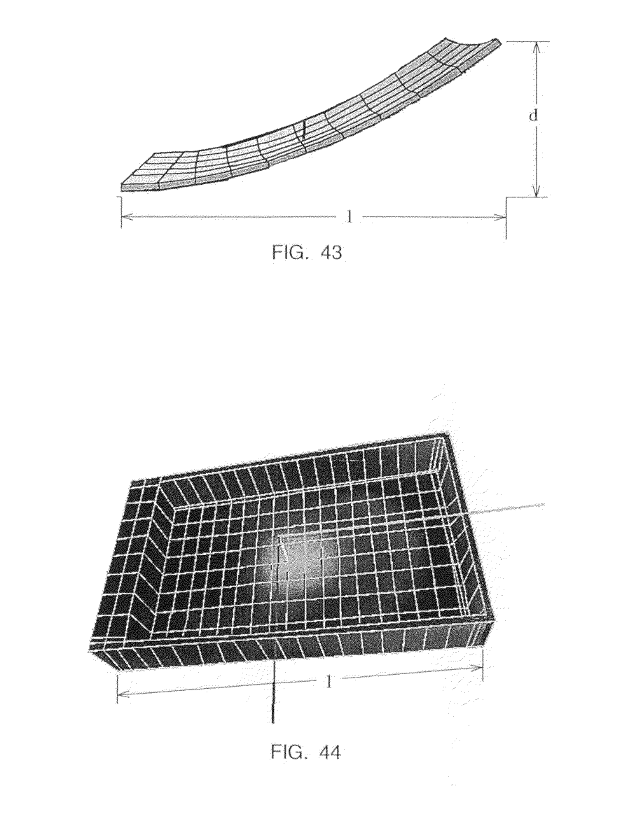

FIG. 43 displays the simulation results of maximal displacement of a flat cantilever 314 which has a maximal bending d of 15 micron, for a length of 350 micro-meters.

The electrodes of both the first and the second sets of electrodes can be in the form of a flat cantilever

FIG. 4 displays the simulation results of maximal displacement of a box-shaped cantilever 315. The maximal displacement in the middle of the box bottom is 0.5 microns for a 350 micro-meter long cantilever 1, (the displacement value is not displayed in the figure).

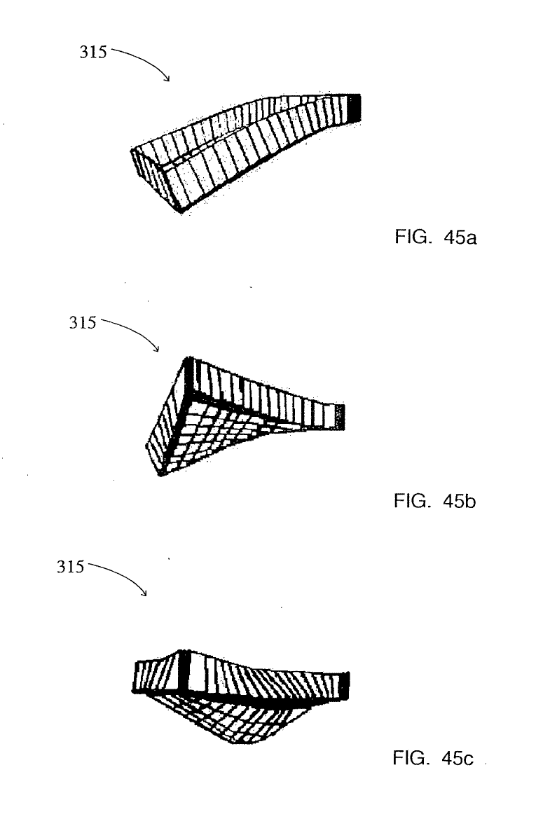

FIGS. 45a-45c displays the simulations results of the mechanical oscillation frequencies for relevant sizes of box-shaped cantilevers to ensure that the RF frequencies of the Paul trap are far from the resonance frequencies of the cantilever. All frequencies for relevant sizes of cantilevers are necessarily below 1 MHz.

The figures show the distortion caused by three natural frequencies.

FIG. 45a shows the distortion caused by oscillation at 0.342781 MHz.

FIG. 45b shows the distortion caused by oscillation at 0.422617 MHz.

FIG. 45c shows the distortion caused by oscillation at 0.678461 MHz.

An example of the qualitative differences between the novel substrate (wafer) material in this invention (sapphire) and commonly used materials can be found in Table 1. The sapphire of the integrated ion chip according to a preferred embodiment of the present invention, is compared with the commonly used silicon and with the ion chip device described in [23], in which the trap is based on a GaAs substrate.

TABLE 1
Substrate comparison of the relevant parameters:

| | | | | Thermal | Dielectric | | | | |
|---|---|---|---|---|---|---|---|---|---|
| | | Young | Thermal | Expansion, | Constant, | | Electrical | | |
| | Density, | Modulus | Conductivity | linear, | [Static/High | | Resistivity, | Breakdown | Loss Tangent, |
| Material | gr/cm³ | (GPa) | Ω/(cm*C. °) | 1/C. ° | Frequency] | | Ω*cm | Field, V/cm | tanδ |
| Si | 2.329 | Y[111] = 165 | 1.3 | 2.6*10⁻⁶ | 11 ÷ 12 | | ~10² (pure) | ~3*10⁴ | 0.005 @ 1 GHz |
| | | Y[110] = 170 | | | | | | | 0.015 @ 10 GHz |
| | | Y[100] = 130 | | | | | | | |
| GaAs | 5.32 | Y[100] = 86 | 0.55 | 5.73*10⁻⁶ | 12.9 | 10.89 | 10⁻³ ÷ 10⁸ | ~4*10⁵ | 0.0016 @ 10 GHz |
| Sapphire | 3.98 | 400 | 0.4 | 4.5*10⁻⁶ | 9.4 | 11.6 | 10¹⁰ | ~10⁶ | (3.0 ÷ 8.6)*10⁻⁵ |
| | | | | | | | | | @10 ÷ 3*10⁹ Hz |

Sapphire, in comparison with Si, and GaAs.
1. Tangent loss: The tangent loss of GaAs and silicon is ˜30 times higher than sapphire. The RF loss using sapphire is much lower. Namely, first the sapphire substrate will absorb less radiation and therefore heat less, and second, consequently the RF energy in the trapping field will be larger and the device will require less power.
2. The breakdown field in sapphire is about 2 times better than GaAs and 30 times better than Silicon. This means that the RF leakage using commonly used materials is higher than when using sapphire. Such a high breakdown point also allows for the miniaturization of DC (e.g. Penning) traps.
3. Electrical resistivity: Sapphire is much better. This means that the risk for electrical leakage between the electrodes is much lower when using sapphire.

UV compatibility: Namely, lack of scattering and absorption of lasers (in the ultra violet range) commonly used to cool, manipulate and read-out ions. 80% external transmission of sapphire is 0.25 um to 4.5 um. This means that sapphire is an easy substrate for use. Transparency also means that back and front side alignment is easy to do when fabricating Sapphire has been selected as a substrate of a preferred embodiment of the present invention as it ensures good standards in all the above relevant parameters. In addition to these qualities, the substrate material is selected such that its qualities meet good resistance to heat, low surface roughness, low secondary electron emission, reasonable thermal conductivity, and good resistance to mechanical deformation.

TABLE 2
Cantilever electrode comparison of relevant parameters:

| | | | | | Thermal | Dielectric | | | | |
|---|---|---|---|---|---|---|---|---|---|---|
| | | | Young | Thermal | Expansion, | Constant, | | Electrical | | |
| | | Density, | Modulus | Conductivity, | linear, | [Static/High | | Resistivity, | Breakdown | Loss Tangent, |
| Material | | gr/cm³ | (GPa) | Ω/(cm*C. °) | 1/C. ° | Frequency] | | Ω*cm | Field, V/cm | tanδ |
| GaAs | | 5.32 | Y[100] = 86 | 0.55 | 5.73*10⁻⁶ | 12.9 | 10.89 | 10⁻³ ÷ 10⁸ | ~4*10⁵ | 0.0016 |
| | | | | | | | | | | @ 10 GHz |
| AlₓGa₁₋ₓAs | | 5.32 − 1.56x | Y[x] = (8.53 − | 0.55 − | (5.73 − | 12.9 − | 10.8 − | 10⁸ ÷ 10¹² | ~(4 ÷ 6)*10⁵ | |
| | | | 0.18x)*10 | 2.12x + | 0.53x)*10⁻⁶ | 2.84x | 2.73x | | | |
| | | | | 2.48x² | | | | | | |
| SiC | 3H—SiC | 3.166, 3.21 | | 3.6 | 3.8*10⁻⁶ | 9.72 | 6.52 | 10² ÷ 10⁶ | ~10⁶ | 0.05 ÷ 0.5 |
| | | | | | | | | | | @ 1 MHz |
| | 4H—SiC | 3.21 | 392 ÷ 694 | 3.7 | | 9.66 | 6.52 | | (3 ÷ 5)*10⁶ | |
| | 6H—SiC | 3.21 | | 4.9 | 4.3 − | 10.03 | 6.7 | | (3 ÷ 5)*10⁶ | |
| | | | | | 4.7*10⁻⁶ | | | | | |

| | | | | | | | | |
|---|---|---|---|---|---|---|---|---|
| Si₃N₄ | 2.5 | 200 | 0.1 | 3*10⁻⁶ | 7.4 | ~10¹⁴ | 10⁷ | 0.0005 ÷ 0.0009 |
| | | | | | | | | @ 1 MHz |

We note that SiC is one of the strongest known materials (relative to weight), a and hence is currently used in state-of-the-art mechanical oscillator construction for a variety of applications. It has never been proposed in the context of ion traps.

As an example we compare SiC with AlGaAs (used in [23] as cantilevers).
1. Young Modulus: SiC is ˜4 times better in terms of stiffness. That means that SiC cm withstand higher force without breaking.
2. The relative low density contributes to less deformations because of weight.
3 The high thermal conductivity will ensure lower temperatures and hence the SiC will be less sensitive to stress deformations.
4. The high electrical conductivity of SiC (which can even be increased by doping) also allows the option of electro-plating processes.

This invention brings forth not only new materials but also new fabrication processes which allow the use of such materials in order to realize the integrated ion chip. Following is a description of the unique processes developed by the inventors of the present invention:

As explained in the following, the development of the processes included sophisticated simulations concerning adhesion, thermal expansion stress, mechanical properties, and so on, resulting in the final choice of materials and processes which lead to the large variety of embodiments made possible by this invention.

For example, in the process flow a layer of Si needs to be deposited in the sapphire (see FIG. 17a,17b) and then cooled from 250 C. Different thermal expansion coefficients cause mechanical stress, and too much stress can lead to a breakdown of the fabrication process or to a deformation of the ion chip. Hence, we have examined several materials such as amorphous Si and poly crystalline Si have been examined, specifically the deformation and stress between amorphous Si and poly crystalline Si, and sapphire. According to the simulation (see FIG. 41) poly crystalline Si experiences a maximal stress of 185 MPa for the thermal expansion coefficient of 29*10(−7) 1/K, while amorphous Si (see FIG. 42) experiences a maximal stress of 887 MPa, for a thermal expansion coefficient (worst case) of 70*10(7) 1/K. Amorphous silicon has another thermal behavior. Its thermal expansion may be negative up to −70*10(−7) 1/K. In this worst case the maximal thermal stress reaches 650 MPa.

The failure stress value is known as between 1300-7000 MPa for Si, the poly crystalline Si deposition will cause huge stress, as it is deposited and after deposition it will cause failure in the process, on the other hand amorphous Si is much more stable for the process.

As another example of the relevant parameters for this invention, simulation of the mechanical robustness of the cantilevers was performed. Such mechanical robustness is crucial for the proper operation of the ion chip as bending of the electrodes may cause them to break or at the very least to change the position of the trap. The commonly used structure is based on flat cantilevers (see FIG. 43), while the unique structure of this invention has the shape of a box (see FIG. 44). The simulations show that with a box structure the maximal displacement in the middle of the box bottom is −0.5 microns (for a 350 micro-meter long cantilever), while the flat shape cantilever has a maximal bending of 15 microns. SiN and similar materials have also been verified to be good enough. This box structure will be used whenever strength is required, e.g. in linear or cross bridge electrodes.

To ensure structural robustness, simulation of the mechanical oscillation frequencies of each of the structure has also been performed to ensure that the RF frequencies of the Paul trap are far from the resonance frequencies of the cantilever. All frequencies for relevant sizes of cantilevers have been verified to be below 1 MHz (see FIG. 45).

In summary:
The required high aspect ratio of cantilever electrodes can be achieved using a box-shaped structure which grants superior qualities compared to the usual flat shape (order of magnitude improvement for the same material thickness).
Box electrodes can be made from SiC or SiN or similar materials of high Young modulus with relatively low density.

Finally, a process was devised to enable high aspect ratio etching into the sapphire substrate (wafer) for the different applications as described (erg. vertical cantilevers, holes for electrical contacts (vias), holes for loading particles, holes for 2-layer traps, etc.). The mask process was optimized, achieving an etch with a depth of 330 micro-meters. As standard (robust) wafers start with a thickness of 300 micro-meters, it was shown that drilling through the fall thickness of the wafer can be obtained. This enables the aforementioned applications requiring holes.

To enable the drilling of holes of different designs and shapes, a mask must be used. A good mask, of course, needs high selectivity to the etching material (in our case reactive ion etching), the problem being that the sapphire is a very hard material and so a mask with high selectivity is hard to find. For example, we achieved a selectivity of more than 7 with electroplated nickel relative to sapphire.

A further problem that needed to be overcome is that even with a selectivity of 7, a mask 50-60 micro-meters thick is required in order to etch more than 300 micro-meters of sapphire. To make such a thick mask with a high spatial resolution of a few microns, a special photolithography process was established with a very thick photo-resist

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

What is claim is:

1. A integrated ion chip comprising:
(a) a substrate having at least one trapping zone wherein said trapping zones are suitable for trapping and cooling ions and other charged particles, a quantum manipulation zone suitable for performing quantum manipulation and read-out, and a translation zone suitable for translation of ions between said trapping zone and said quantum manipulation zone;
(b) a first set of electrodes, having a beam air bridge formation, wherein each of said electrodes of first set of electrodes has two bases, one at each end of, wherein each one of said electrodes of first set of electrodes bases is disposed on said substrate upon a gradation in a locations suitable for trapping ions or other charged particles;
(c) a second set of electrodes, wherein each one of said electrodes of said second set of electrodes, has one base at one end of said electrode of second set of electrodes, wherein each one of said bases of second set of electrodes is disposed on said substrate upon one of said gradations in locations suitable for performing quantum manipulation on ions; and
(d) electrical contacts disposed on said substrate of a quantity and in locations suitable for connecting to each of both said bases of first set of electrodes and to each of said bases of second set of electrodes.

2. The integrated ion chip of claim 1, wherein each of said electrodes of said first set of electrodes and each of said electrodes of said second set of electrodes includes:
(i) a core layer granting said electrode of said second set of electrodes mechanical structural integrity;
(ii) a first adhesion layer coating on an external surface of said core layer, granting said electrode of said second set of electrodes an adhesive quality;
(iii) a second adhesion layer coating an external surface of said core layer, granting said electrode of said second set of electrodes an adhesive quality; and
(iv) a conductive layer coating on said first adhesion layer for granting said electrode of said second set of electrodes a required conductivity.

3. The integrated ion chip of clam 2, wherein said substrate is made of sapphire.

4. The integrated ion chip of claim 2, wherein said substrate is made of a material selected from a group consisting of sapphire, alumina, and aluminum nitride.

5. The integrated ion chip of claim 3, wherein said core layer is made of silicon carbide, and said conductive layer is made of gold.

6. The integrated ion chip of claim 4, wherein said core layer is made of silicon carbide, and said conductive layer is made of gold.

7. The integrated ion chip of claim 3, wherein said core layer is made of a material selected from a group consisting of silicon carbide, silicon nitride, and tungsten.

8. The integrated ion chip of claim 4, wherein said core layer is made of a material selected from a group consisting of silicon carbide, silicon nitride, and tungsten.

9. The integrated ion chip of claim 3, wherein said conductive layer is made of a material selected from a group consisting of gold, silver, tungsten and copper.

10. The ion chip of claim 4, wherein said conductive layer is made of a material selected from a group consisting of gold, silver, tungsten and copper.

11. The integrated ion chip of claim 3, wherein said adhesion layers are made of a material selected from a group consisting of titanium, chromium and tungsten.

12. The integrated ion chip of claim 4, wherein said adhesion layers are made of a material selected from a group consisting of titanium, chromium and tungsten.

13. The integrated ion chip of claim 1, wherein said substrate has a tangent loss, a breakdown field, and a Young modulus, at least as good as those of sapphire.

14. The integrated ion chip of claim 2, wherein said core layer is made of material having a Young modulus, a density and a thermal conductivity at least as good as those of SiC, and low tangent loss as good as that of SiC.

15. A process for fabrication of an integrated ion chip, the process comprising the stages of:
(a) a preliminary preparatory stage including the step of:
(i) providing a substrate having an external form of a three-dimensional cube, with dimensions, a first main side having a surface, and a second main side having a surface;
(b) a first etching stage in which internal zones in said substrate are designed on said first main side, while at least part of said internal zones have gradated walls serving as gradations;
(c) a first electrode construction stage in which electrodes are constructed to be connected to said substrate; and
(d) a first removal stage in which excess materials left over from said process, which have no use as a component of said integrated ion chip, are removed from said substrate and from said electrodes.

16. The process for fabrication of claim 15 further comprising the stages of:
(e) a second etching stage in which internal zones in said substrate are designed in said second main side, while at least part of said internal zones have gradated walls serving as gradations; and
(f) a second electrode construction stage in which electrodes are constructed to be connected to said substrate.

17. The process for fabrication of claim 15 further comprising the stage of:
(e) electroplating of an Au layer on said electrodes and on areas to serve as electrical contacts.

18. The process for fabrication of claim 17 wherein said preliminary preparatory stage ter includes the steps of:
(ii) polishing both of said main sides.

19. The process for fabrication of claim 18 wherein said preliminary preparatory stage further including the steps of:
(iii) positions of seed layer on the entire surface of said first main side of said substrate; and
(iv) spinning of photoresist on the entire surface of said first main side of said substrate.

20. The process for fabrication of claim 19 wherein said preliminary preparatory stage further includes the steps of:
(v) electroplating of a Ni mask through said photoresist; and
(vi) stripping of said photoresist.

21. The process for fabrication of claim 20 wherein said preliminary preparatory stage her includes the step of:
(vii) removing said seed layer by means nickel etching.

22. The process for fabrication of claim 21 wherein said first etching stage includes the steps of:
(i) deep reactive ion etching in chlorine-based plasma; and
(ii) deposition of a seed layer on an entire surface of said fust main side of said substrate.

23. The process for fabrication of claim 22 wherein said first etching stage further includes the steps of:
(iii) spinning of photoresist;
(iv) photoresist pattering; and
(v) electroplating of Ni mask through said photoresist.

24. The process for fabrication of claim 23 wherein said first etching stage further includes the steps of:
(vi) stripping said photoresist;
(vii) removing said seed layer by nickel etching; and
(viii) deep reactive ion etching in chlorine-based plasma.

25. The process for fabrication of claim 15 wherein said first electrode construction stage includes the steps of:
(i) deposition of a Si layer and trench filling; and
(ii) spinning of photoresist.

26. The process for fabrication of claim 25 wherein said first electrode construction stage further includes the steps of:
(ii) patterning of said photoresist;
(iv) reactive ion etching of said Si in fluorine-based plasma; and
(v) stripping of said photoresist.

27. The process for fabrication of claim 26 wherein said first electrode construction stage further includes the steps of:
(vi) adhesion layer sputtering;
(vii) SiC layer depositing; and
(viii) said SiC planarization.

28. The process for fabrication of claim 27 wherein said first electrode construction stage further includes the steps of:
(ix) adhesion layer sputtering; and
(x) polymer spinning.

29. The process for fabrication of claim 28 wherein said first electrode construction stage further includes the steps of:
(xi) polymer planarization; and then
(xii) spinning of photoresist; and then
(xiii) photoresist patterning; and
(xiv) thermal evaporation of Au.

30. The process for fabrication of claim 15 wherein said first removal stage includes the steps of:
(i) photoresist removal;
(ii) wet etching; and
(iii) polymer stripping.

31. The process for fabrication of claim 30 wherein said first removal stage her includes the steps of:
(iv) selective isotropic etching of a silicon sacrificial layer.

32. The process for fabrication of claim 17 wherein said preliminary preparatory stage further includes the steps of:
(ii) positioning of seed layer on the entire surface of said first main side of said substrate;
(iii) spinning of photoresist on the entire surface of said first main side of said substrate;
(iv) electroplating of a Ni mask through said photoresist; and
(v) stripping of said photoresist;
wherein said first etching stage includes the steps of:
(i) deep reactive ion etching in chlorine-based plasma;
(ii) deposition of a seed layer on an entire surface of said of said first main side of said substrate;
(iii) spinning of photoresist;
(iv) said photoresist patterning;
(v) electroplating of Ni mask through said photoresist;
(vi) stripping of said photoresist;
(vii) removing of said seed layer by nickel etching; and
(viii) deep reactive ion etching in chlorine-based plasma;
wherein said first electrode construction stage includes the steps of:
(i) deposition of a Si layer and trench filling;
(ii) spinning of photoresist;
(iii) said photoresist patterning;
(iv) reactive ion etching of Si in fluorine-based plasma;
(v) stripping of said photoresist;
(vi) adhesion layer sputtering;
(vii) SiC layer depositing;
(vii) said SiC planarization;
(ix) adhesion layer sputtering;
(x) polymer spinning;
(xi) said polymer planarization;
(xii) spinning of photoresist; and then
(xiii) photoresist patterning; and
(xiv) thermal evaporation of Au;
and wherein said removal stage includes the steps of:
(i) photoresist removal;
(ii) wet etching;
(iii) polymer stripping; and
(iv) selective isotropic etching of a silicon sacrificial layer.

33. The integrated ion chip of claim 1 further comprising at least one cantilever made by high aspect ratio deep etching.

34. The integrated ion chip of claim 1 further comprising at least one hole in said substrate, for electrical contacts.

35. The integrated ion chip of claim 1 further comprising at least one hole in said substrate, for charged particle loading.

36. The integrated ion chip of claim 1 wherein each one of said electrodes of said second set of electrodes consisting of a simple flat structure of a flat geometry.

37. The integrated ion chip of claim 1, wherein each one of said electrodes of said second set of electrodes consisting of a simple plate structure of a box-like geometry for increased strength.
